(19) United States
(12) Patent Application Publication
(10) Pub. No.: US 2018/0253004 A1
(43) Pub. Date: Sep. 6, 2018

(54) PHOTOSENSITIVE RESIN COMPOSITION AND ORGANIC INSULATING FILM PREPARED THEREFROM

(71) Applicant: Rohm and Haas Electronic Materials Korea Ltd., Cheonan (KR)

(72) Inventors: Jung-Hwa Lee, Hwaseong (KR); Ju-Young Jung, Hwaseong (KR); Seung-Ho Kwon, Hwaseong (KR); Seung-Keun Kim, Hwaseong (KR); Yu-Jin Chae, Hwaseong (KR)

(21) Appl. No.: 15/755,580

(22) PCT Filed: Aug. 31, 2016
(86) PCT No.: PCT/KR2016/009696

§ 371 Date: Feb. 27, 2018

(30) Foreign Application Priority Data
Oct. 1, 2015 (KR) 10-2015-0138473
Aug. 30, 2016 (KR) 10-2016-0110788

(51) Int. Cl. G03F 7/033; G03F 7/004; H01B 3/44

(52) U.S. Cl. CPC G03F 7/033; G03F 7/031; H01B 3/447; G03F 7/0048

(57) ABSTRACT

Disclosed herein are a photosensitive resin composition and an organic insulating film prepared therefrom. By optimizing the weight average molecular weight of a copolymer, and using a specific solvent in the photosensitive resin composition, a coated film obtained therefrom may have high planarity property and patterns with high resolution. Accordingly, the photosensitive resin composition may be used as a material for an organic insulating film simultaneously functioning as white pixels.

### TECHNICAL FIELD

The present invention relates to a photosensitive resin composition and an organic insulating film prepared therefrom, in particular a negative-type photosensitive resin composition for the formation of a film having patterns with high planarity and high resolution, and an organic insulating film prepared using same, which can simultaneously function as white pixels in a liquid crystal display.

### BACKGROUND ART

In a display such as a thin film transistor (TFT)-type liquid crystal display, an organic insulating film is used to protect and insulate TFT circuits. Recently, in order to meet the high resolution requirement for a display, the size of pixels tends to gradually decrease, which may cause undesirable decrease of an aperture ratio. In order to resolve this problem, a white pixel in addition to blue, green and red pixels is introduced in a display. In such case, however, an additional process for introducing white pixels is required.

Accordingly, a method for introducing white pixels by using an organic insulating film receives much attention. That is, after the formation of a colored film on a part of a substrate, a composition for a transparent organic insulating film is coated on the entire substrate having both of a region where a colored film is formed and a region where a colored film is not formed, and then cured. In the region where the colored film is not formed, the cured film may function as both white pixels and an organic insulating film. In this method, however, due to the height difference between the region with the colored film and the region without the colored film, the surface of the organic insulating film is unevenly formed, thereby increasing defects in a liquid crystal display.

Among various compositions that may be used for preparing a film having both functions of a white pixel and a protective film, Korean Patent No. 10-1336305 discloses a composition comprising a copolymer of an unsaturated compound containing an epoxy group and an ethylenically unsaturated compound, as a binder resin. However, a film prepared by using the composition of this patent, which is a thermosetting resin composition, cannot have high resolution patterns due to the difficulty in the formation of patterns.

### DISCLOSURE OF INVENTION

### Technical Problem

An object of the present invention is to provide a photosensitive resin composition which may produce patterns satisfying both high planarity and high resolution, and an organic insulating film manufactured therefrom.

### Solution to Problem

According to one aspect of the present invention, there is provided a photosensitive resin composition, which comprises (1) a copolymer having a weight average molecular weight of 3,000 to 7,000; (2) a polymerizable unsaturated compound; (3) a photopolymerization initiator; and (4) a solvent comprising a high boiling point solvent having a boiling point of 180° C. or higher in an atmospheric pressure.

In addition, there is provided an organic insulating film formed using the photosensitive resin composition.

### Advantageous Effects of Invention

The photosensitive resin composition of the present invention may produce a film having patterns of high planarity and high resolution, and may be used as a material for an organic insulating film, etc. and is appropriate for accomplishing both functions of an organic insulating film and a white pixel in a liquid crystal display.

### BRIEF DESCRIPTION OF DRAWINGS

FIG. 1 illustrates a method of measuring the planarity of an organic insulating film manufactured using a photosensitive resin composition (10: organic insulating film, 20: lower cured film, and 30: substrate).

### BEST MODE FOR CARRYING OUT THE INVENTION

The present invention provides a photosensitive resin composition, which comprises (1) a copolymer having a weight average molecular weight of 3,000 to 7,000; (2) a polymerizable unsaturated compound; (3) a photopolymerization initiator; and (4) a solvent comprising a high boiling point solvent having a boiling point of 180° C. or higher in an atmospheric pressure.

Hereinafter, the photosensitive resin composition will be explained in detail.

In the present description, “(meth)acryl” means “acryl” and/or “methacryl”, and “(meth)acrylate” means “acrylate” and/or “methacrylate”.

(1) Copolymer (Alkali-Soluble Resin)

The photosensitive resin composition of the present invention may include a copolymer, which may be a random copolymer.

The copolymer may include (1-1) a structural unit derived from an ethylenically unsaturated carboxylic acid, an ethylenically unsaturated carboxylic anhydride or a mixture thereof, and (1-2) a structural unit derived from an ethylenically unsaturated compound containing an aromatic ring, and may selectively include (1-3) a structural unit derived from an ethylenically unsaturated compound different from the structural units (1-1) and (1-2). The copolymer may correspond to an alkali-soluble resin for achieving desired developability during the development step and may function as both of a basic support for forming a film after coating and a structure for final patterns.

(1-1) Structural Unit Derived from an Ethylenically Unsaturated Carboxylic Acid, an Ethylenically Unsaturated Carboxylic Anhydride, or a Mixture Thereof

In the present invention, the structural unit (1-1) is derived from an ethylenically unsaturated carboxylic acid, an ethylenically unsaturated carboxylic anhydride, or a mixture thereof. The ethylenically unsaturated carboxylic acid, the ethylenically unsaturated carboxylic anhydride, or the mixture thereof is a polymerizable unsaturated monomer having at least one carboxyl group in a molecule. Examples thereof include an unsaturated monocarboxylic acid such as (meth)acrylic acid, crotonic acid, alpha-chloroacrylic acid, and cinnamic acid; an unsaturated dicarboxylic acid and an anhydride thereof such as maleic acid, maleic anhydride, fumaric acid, itaconic acid, itaconic anhydride, citraconic acid, citraconic anhydride, and mesaconic acid; an unsaturated polycarboxylic acid of trivalence or more and an anhydride thereof; and a mono[(meth)acryloyloxyalkyl] ester of a polycarboxylic acid of divalence or more such as mono[2-(meth)acryloyloxyethyl] succinate, and mono[2-(meth)acryloyloxyethyl] phthalate, but are not limited thereto. In terms of developability, (meth)acrylic acid is preferred among them.

The amount of the structural unit (1-1) derived from an ethylenically unsaturated carboxylic acid, an ethylenically unsaturated carboxylic anhydride, or a mixture thereof may be 5 to 98 mole %, preferably 15 to 50 mole % based on the total number of moles of the structural units constituting the copolymer to maintain good developability.

(1-2) Structural Unit Derived from an Ethylenically Unsaturated Compound Containing an Aromatic Ring

In the present invention, the structural unit (1-2) is derived from an ethylenically unsaturated compound containing an aromatic ring, and examples of the ethylenically unsaturated compound containing an aromatic ring may be at least one selected form the group consisting of phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tribromophenyl (meth)acrylate; styrene; styrene containing an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; styrene having halogen such as fluorostyrene, chlorostyrene, bromostyrene, and iodostyrene; styrene having an alkoxy substituent such as methoxystyrene, ethoxystyrene, and propoxystyrene; 4-hydroxy styrene, p-hydroxy-α-methylstyrene, acetylstyrene; vinyltoluene, divinylbenzene, vinylphenol, o-vinylbenzyl methyl ether, m-vinylbenzyl methyl ether, p-vinylbenzyl methyl ether, o-vinylbenzyl glycidyl ether, m-vinlbenzyl glycidyl ether, and p-vinylbenzyl glycidyl ether, and preferably, may be styrene compounds in consideration of polymerization properties.

The amount of the structural unit (1-2) derived from an ethylenically unsaturated compound containing an aromatic ring may be 2 to 95 mole %, preferably 10 to 60 mole % in consideration of chemical resistance, based on the total number of moles of the structural units constituting the copolymer.

The copolymer of the present invention may additionally include a structural unit (1-3) derived from an ethylenically unsaturated compound different from the structural units (1-1) and (1-2).

(1-3) Structural Unit Derived from an Ethylenically Unsaturated Compound Different from the Structural Units (1-1) and (1-2)

In the present invention, the structural unit (1-3) is derived from an ethylenically unsaturated compound different from the structural units (1-1) and (1-2), and the ethylenically unsaturated compound different from the structural units (1-1) and (1-2) may be at least one selected from the group consisting of an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl-α-hydroxymethylacrylate, ethyl-α-hydroxymethylacrylate, propyl-α-hydroxymethylacrylate, butyl-α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; an ethylenically unsaturated compound containing an epoxy group such as glycidyl (meth)acrylate, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, and 3,4-epoxycyclohexyl (meth)acrylate; a tertiary amine containing an N-vinyl group such N-vinyl pyrrolidone, N-vinyl carbazole and N-vinyl morpholine; an unsaturated ether such as vinyl methyl ether and vinyl ethyl ether; an unsaturated ether containing an epoxy group such as allyl glycidyl ether, and 2-methylallyl glycidyl ether; and an unsaturated imide such as maleimide, N-phenylmaleimide, N-(4-chlorophenyl)maleimide, N-(4-hydroxyphenyl)maleimide and N-cyclohexylmaleimide. Particularly, the structural unit (1-3) may be an ethylenically unsaturated compound containing an epoxy group in consideration of the improvement of copolymerization properties and the strength of an insulating film, preferably, glycidyl (meth)acrylate, 4-hydroxybutyl acrylate glycidyl ether, or 3,4-epoxycyclohexyl (meth)acrylate. More preferably, 3,4-epoxycyclohexyl (meth)acrylate may be used in consideration of chemical resistance and retention rate.

The amount of the structural unit (1-3) derived from an ethylenically unsaturated compound different from the structural units (1-1) and (1-2) may be 0 to 75 mole %, preferably 10 to 65 mole %, based on the total number of moles of the structural units constituting the copolymer. Within this amount range, the storage stability of a composition may be maintained and the retention rate may be improved.

The copolymer (1) may include a (meth)acrylic acid/styrene copolymer, a (meth)acrylic acid/benzyl (meth)acrylate copolymer, a (meth)acrylic acid/styrene/methyl (meth)acrylate copolymer, a (meth)acrylic acid/styrene/methyl (meth)acrylate/glycidyl methacrylate copolymer, a (meth)acrylic acid/styrene/methyl (meth)acrylate/3,4-epoxycyclohexyl (meth)acrylate copolymer, a (meth)acrylic acid/styrene/methyl (meth)acrylate/4-hydroxybutylacrylate glycidyl ether copolymer, a (meth)acrylic acid/styrene/methyl (meth)acrylate/glycidyl methacrylate/3,4-epoxycyclohexyl (meth)acrylate copolymer, a (meth)acrylic acid/styrene/methyl (meth)acrylate/4-hydroxybutylacrylate glycidyl ether/3,4-epoxycyclohexyl (meth)acrylate copolymer, a (meth)acrylic acid/styrene/methyl (meth)acrylate/glycidyl methacrylate/N-phenylmaleimide copolymer, a (meth)acrylic acid/styrene/methyl (meth)acrylate/glycidyl methacrylate/N-cyclohexyl maleimide copolymer, a (meth)acrylic acid/styrene/n-butyl (meth)acrylate/glycidyl methacrylate/N-phenyl maleimide copolymer, or a mixture thereof. One or more copolymers may be included in the photosensitive resin composition.

The copolymer (1) may be prepared by charging a molecular weight regulator, a radical polymerization initiator, a solvent, and respective compounds that provide the structural units (1-1), (1-2), and (1-3), introducing nitrogen, and subjecting the mixture to polymerization with slow agiration. The copolymer (1) may be prepared as a random copolymer.

The molecular weight regulator may be a mercaptan compound such as butyl mercaptan and octyl mercaptan, or an α-methylstyrene dimer, but is not limited thereto.

The radical polymerization initiator may be at least one selected from the group consisting of an azo compound such as 2,2′-azobisisobutyronitrile, 2,2′-azobis(2,4-dimethylvaleronitrile), and 2,2′-azobis(4-methoxy-2,4-dimethylvaleronitrile), benzoyl peroxide, lauryl peroxide, t-butyl peroxypivalate and 1,1-bis(t-butylperoxy)cyclohexane, but is not limited thereto.

Also, the solvent may be any conventional solvent commonly used in the manufacturing of a copolymer and may include, e.g., methyl 3-methoxypropionate or propylene glycol monomethyl ether acetate (PGMEA).

The copolymer (1) may be used in an amount of 0.5 to 75 wt %, preferably 5 to 65 wt %, based on the total weight of the photosensitive resin composition excluding solvents. Within this range, the composition would produce a patterned film having a good profile after development with improved properties such as chemical resistance. The weight average molecular weight (Mw) of the copolymer (1) thus prepared may be in the range of 3,000 to 7,000, or 4,000 to 6,000, when determined by gel permeation chromatography (GPC, using tetrahydrofuran as an eluent) referenced to polystyrene. Within this range, the composition would have desirable improvements in planarity and a good pattern profile after development.

(2) Polymerizable Unsaturated Compound

The photosensitive resin composition of the present invention may include a polymerizable unsaturated compound.

The polymerizable unsaturated compound may be any compound to be polymerized by a polymerization initiator and may be a monofunctional or polyfunctional ester compound of acrylic acid or methacrylic acid having at least one ethylenically unsaturated group. A polyfunctional compound having at least two functional groups may be preferred in consideration of chemical resistance.

The polymerizable unsaturated compound may be selected from the group consisting of ethylene glycol di(meth)acrylate, propylene glycol di(meth)acrylate, diethylene glycol di(meth)acrylate, triethylene glycol di(meth)acrylate, 1,6-hexanediol di(meth)acrylate, polyethylene glycol di(meth)acrylate, polypropylene glycol di(meth)acrylate, glycerin tri(meth)acrylate, trimethylolpropane tri(meth)acrylate, pentaerythritol tri(meth)acrylate, monoester of pentaerythritol tri(meth)acrylate and succinic acid, pentaerythritol tetra(meth)acrylate, dipentaerythritol penta(meth)acrylate, dipentaerythritol hexa(meth)acrylate, monoester of dipentaerythritol penta(meth)acrylate and succinic acid, caprolactone modified dipentaerythritol hexa(meth)acrylate, pentaerythritol triacrylate hexamethylene diisocyanate (a reactant of pentaerythritol triacrylate and hexamethylene diisocyanate), tripentaerythritol hepta(meth)acrylate, tripentaerythritol octa(meth)acrylate, bisphenol A epoxyacrylate, and ethylene glycol monomethyl ether acrylate, but is not limited thereto.

Besides the above examples, the polymerizable unsaturated compound may be a polyfunctional urethane acrylate compound obtained from the reaction of a compound having a straight chain alkylene group, an alicyclic structure and at least two isocyanate groups, and a compound having at least one hydroxyl group in a molecule, three, four or five acryloyloxy groups and/or methacryloyloxy groups, but is not limited thereto.

Examples of commercially available polymerizable unsaturated compounds may include (i) monofunctional (meth)acrylate such as Aronix M-101, M-111, and M-114 manufactured by Toagosei Co., Ltd., KAYARAD T4-110S, and T4-120S manufactured by Nippon Kayaku Co., Ltd., and V-158, and V-2311 manufactured by Osaka Yuki Kagaku Kogyo Co., Ltd.; (ii) bifunctional (meth)acrylate such as Aronix M-210, M-240, and M-6200 manufactured by Toagosei Co., Ltd., KAYARAD HDDA, HX-220, and R-604 manufactured by Nippon Kayaku Co., Ltd., and V-260, V-312, and V-335 HP manufactured by Osaka Yuki Kagaku Kogyo Co., Ltd.; and (iii) tri and more functional (meth)acrylate such as Aronix M-309, M-400, M-403, M-405, M-450, M-7100, M-8030, M-8060, and TO-1382 manufactured by Toagosei Co., Ltd., KAYARAD TMPTA, DPHA, DPHA-40H, DPCA-20, DPCA-30, DPCA-60, and DPCA-120 manufactured by Nippon Kayaku Co., Ltd., and V-295, V-300, V-360, V-GPT, V-3PA, V-400, and V-802 manufactured by Osaka Yuki Kagaku Kogyo Co., Ltd.

The polymerizable unsaturated compound (2) may be used alone or in combination of two or more thereof.

The amount of the polymerizable unsaturated compound (2) may be 5 to 200 parts by weight, preferably 10 to 150 parts by weight, based on 100 parts by weight of the copolymer (1) excluding solvents. Within this range, the resin composition would readily form a patterned film having a good contact hole profile.

(3) Photopolymerization Initiator

The photopolymerization initiator of the present invention may be a compound that initiates polymerization of curable monomers upon exposure to light such as visible rays, ultraviolet rays, and deep-ultraviolet radiation. The photopolymerization initiator may be a radical initiator, which is not specifically limited but may be at least one selected from the group consisting of an acetophenone compound, a benzophenone compound, a benzoin compound, a benzoyl compound, a xanthone compound, a triazine compound, a halomethyloxadiazole compound, and a lophine dimer compound.

Particular examples of the photopolymerization initiator may include, but are not limited to, 2,2′-azobis(2,4-dimethylvaleronitrile), 2,2′-azobis(4-methoxy-2,4-dimethylvaleronitrile), benzoyl peroxide, lauryl peroxide, t-butyl peroxypivalate, 1,1-bis(t-butyl peroxy)cyclohexane, p-dimethylamino acetophenone, 2-benzyl-2-(dimethylamino)-1-[4-(4-morpholinyl)phenyl]-1-butanone, 2-hydroxy-2-methyl-1-phenyl-propan-1-one, benzyl dimethyl ketal, benzophenone, benzoin propyl ether, diethyl thioxanthone, 2,4-bis(trichloromethyl)-6-p-methoxyphenyl-s-triazine, 2-trichloromethyl-5-styryl-1,3,4-oxodiazole, 9-phenylacridine, 3-methyl-5-amino-((s-triazin-2-yl)amino)-3-phenylcoumarin, a 2-(o-chlorophenyl)-4,5-diphenylimidazolyl dimer, 1-phenyl-1,2-propanedione-2-(o-ethoxycarbonyl)oxime, 1-[4-(phenylthio)phenyl]-octane-1,2-dione-2-(O-benzoyloxime), o-benzoyl-4′-(benzmercapto)benzoyl-hexyl-ketoxime, 2,4,6-trimethylphenylcarbonyl-diphenylphosphonyloxide, hexafluorophosphoro-trialkylphenyl sulfonium salt, 2-mercaptobenzimidazole, 2,2′-benzothiazolyl disulfide and a mixture thereof.

Alternatively, the photopolymerization initiator may include at least one kind of an oxime compound. The oxime compound may include any radical initiator having an oxime structure without specific limitation, and may include, e.g., an oxime ester compound.

Preferred for high sensitivity are one or more oxime compounds disclosed in KR 2004-0007700, KR 2005-0084149, KR 2008-0083650, KR 2008-0080208, KR 2007-0044062, KR 2007-0091110, KR 2007-0044753, KR 2009-0009991, KR 2009-0093933, KR 2010-0097658, KR 2011-0059525, KR 2011-0091742, KR 2011-0026467, KR 2011-0015683, WO 2010/102502 and WO 2010/133077. Particular examples of commercially available photopolymerization initiators include OXE-01 (BASF), OXE-02 (BASF), OXE-03 (BASF), N-1919 (ADEKA), NCI-930 (ADEKA), NCI-831 (ADEKA) and the like.

The photopolymerization initiator (3) may be included in an amount of 1 to 20 parts by weight, preferably 3 to 17 parts by weight, based on 100 parts by weight of the copolymer (1) (based on the solid content). Within this range, highly sensitive patterns having good pattern developability and coatability may be obtained.

(4) Solvent

The solvent (4) of the present invention may include a high boiling point solvent, which has a boiling point of 180° C. or higher under an atmospheric pressure.

The high boiling point solvent may have a boiling point of 180° C. or higher, preferably 180 to 250° C., and more preferably 190 to 210° C. under an atmospheric pressure. The amount of the high boiling point solvent is preferably 5 to 60 wt %, more preferably 10 to 50 wt %, and more preferably 15 to 40 wt % based on the total weight of the solvent (4). Within this range, a highly planarized coated film may be obtained.

Examples of the high boiling point solvent may include at least one selected from the group consisting of gamma butyrolactone, diethylene glycol monomethyl ether, diethylene glycol monobutyl ether, propylene glycol diacetate, diethylene glycol monoethyl ether, diethylene glycol monoethyl ether acetate, diethylene glycol monobutyl ether acetate, ethylene glycol monobutyl ether acetate, diethylene glycol diethyl ether, dipropylene glycol methyl ether acetate, N-methylformamide, N,N-dimethylformamide, N-methyl formanilide, N-methyl acetamide, N,N-dimethyl acetamide, N-methyl pyrrolidone, dimethyl sulfoxide, benzyl ethyl ether, dihexyl ether, acetonylacetone, isophorone, caproic acid, caprylic acid, 1-octanol, 1-nonanol, benzyl acetate, ethyl benzoate, diethyl oxalate, diethyl maleate, ethylene carbonate, propylene carbonate and phenyl cellosolve acetate. In consideration of developability, preferably, the high biling point solvent may be at least one selected from the group consisting of gamma butyrolactone, diethylene glycol monomethyl ether, diethylene glycol monobutyl ether, propylene glycol diacetate, diethylene glycol monoethyl ether, diethylene glycol monoethyl ether acetate and diethylene glycol monobutyl ether acetate.

The solvent (4) of the present invention may additionally include a low boiling point solvent (4-1) having a boiling point lower than 180° C. The low boiling point solvent (4-1) has compatibility with the above-described components in the photosensitive resin composition but not react with the components, and may include any known solvent having a boiling point lower than 180° C., and preferably of 100° C. or higher and lower than 180° C. under an atmospheric pressure, which may be conventionally used in a photosensitive resin composition.

Examples of the low boiling point solvent may be at least one selected from the group consisting of propylene glycol monomethyl ether acetate, cyclohexanone, dipropylene glycol dimethyl ether, ethylene glycol monomethyl ether, ethylene glycol monoethyl ether, ethylene glycol-n-propyl ether, propylene glycol monomethyl ether, propylene glycol monoethyl ether, propylene glycol mono-n-propyl ether, ethylene glycol monomethyl ether acetate, ethylene glycol monoethyl ether acetate, diethylene glycol dimethyl ether, tetrahydrofuran, methyl ethyl ketone, 2-heptanone, 3-heptanone, ethyl acetate, n-propyl acetate, isopropyl acetate, n-butyl acetate, isobutyl acetate, n-pentyl formate, isopentyl acetate, n-butyl propionate, ethyl butyrate, n-propyl butyrate, isopropyl butyrate, n-butyl butyrate, methyl pyruvate, ethyl pyruvate, n-propyl pyruvate, N,N-dimethylformamide, N,N-dimethylacetamide, 3-methoxybutanol, and cyclopentanone. Preferably, propylene glycol monomethyl ether acetate may be used in consideration of compatibility with other components.

The amount of the solvent (4) in the photosensitive resin composition of the present invention is not specifically limited. For the good coatability and stability of the photosensitive resin composition, the solvent may be contained in an amount such that the solid content of the composition ranges from 5 to 70 wt %, preferably 10 to 55 wt %, based on the total weight of the composition. Here, the solid content means the amount of the components excluding the solvents in the resin composition.

(5) Surfactant

The photosensitive resin composition of the present invention may further include a surfactant as occasion demands to enhance its coatability and to prevent the formation of defects.

The surfactants are not limited, but preferred are fluorine-based surfactants, silicon-based surfactants, non-ionic surfactant and the like.

Examples of the surfactants may include fluorine- and silicon-based surfactants such as BM-1000, and BM-1100 manufactured by BM CHEMIE Co., Ltd., Megapack 6-142 D, 6-172, 6-173, 6-183, F-470, F-471, F-475, F-482, and F-489 manufactured by Dai Nippon Ink Kagaku Kogyo Co., Ltd., Florad F4-135, F4-170 C, FC-430, and FC-431 manufactured by Sumitomo 3M Ltd., Sufron S-112, S-113, S-131, S-141, S-145, S-382, S4-101, S4-102, S4-103, S4-104, S4-105, and S4-106 manufactured by Asahi Glass Co., Ltd., Eftop EF301, EF303, and EF352 manufactured by Shinakida Kasei Co., Ltd., SH-28 PA, SH-190, SH-193, SZ-6032, SF-8428, DC-57, and DC-190 manufactured by Toray Silicon Co., Ltd., DC3PA, DC7PA, SH11PA, SH21PA, SH8400, FZ-2100, FZ-2110, FZ-2122, FZ-2222, and FZ-2233 manufactured by Dow Corning Toray Silicon Co., Ltd., TSF-4440, TSF-4300, TSF-4445, TSF-4446, TSF-4460, and TSF-4452 manufactured by GE Toshiba Silicon Co., Ltd., and BYK-333 manufactured by BYK Co., Ltd.; non-ionic surfactants such as polyoxyethylene alkyl ethers including polyoxyethylene lauryl ether, polyoxyethylene stearyl ether, polyoxyethylene oleyl ether, and the like, polyoxyethylene aryl ethers including polyoxyethylene octylphenyl ether, polyoxyethylene nonylphenyl ether, and the like, and polyoxyethylene dialkyl esters including polyoxyethylene dilaurate, polyoxyethylene distearate, and the like; and organosiloxane polymer KP341 (manufactured by Shin-Etsu Kagaku Co., Ltd.), (meth)acrylate-based copolymer Polyflow No. 57 and 95 (Kyoei Yuji Kagaku Co., Ltd.), and the like

These surfactants may be used alone or in combination of two or more thereof.

The surfactant (5) may be contained in an amount such that the solid content excluding solvents ranges from 0.001 to 5 parts by weight, preferably 0.05 to 3 parts by weight, based on 100 parts by weight of the copolymer (1). Within the amount range, the composition can be readily coated.

(6) Adhesion Assisting Agent

The photosensitive resin composition of the present invention may additionally include an adhesion assisting agent to improve the adhesiveness of a coating to a substrate.

The adhesion assisting agent is not limited to specific kinds, however may include, e.g., a silane coupling agent containing at least one reactive group selected from the group consisting of a carboxyl group, a (meth)acryloyl group, an isocyanate group, an amino group, a mercapto group, a vinyl group and an epoxy group.

Preferred adhesion assisting agent may include trimethoxysilyl benzoic acid, γ-methacryloxypropyltrimethoxysilane, vinyltriacetoxysilane, vinyltrimethoxysilane, γ-isocyanatopropyltriethoxysilane, γ-isocyanatepropyltriethoxysilane, γ-glycidoxypropyltrimethoxysilane, γ-glycidoxypropyltriethoxysilane, N-phenylaminopropyltrimethoxysilane, β-(3,4-epoxycyclohexyl)ethyltrimethoxysilane, or a mixture thereof, and more preferably may include γ-glycidoxypropyltriethoxysilane, γ-glycidoxypropyltrimethoxysilane, N-phenylaminopropyltrimethoxysilane and the like, which may increase retention rate and have good adhesiveness of a coating to a substrate. In addition, γ-isocyanatepropyltriethoxysilane containing an isocyanate group (e.g., KBE-9007 manufactured by Shin-Etsu Co., Ltd.) may be used to improve chemical resistance.

The adhesion assisting agent (6) may be contained in an amount such that the solid content excluding solvents ranges from 0.001 to 5 parts by weight, preferably 0.05 to 3 parts by weight based on 100 parts by weight of the copolymer (1). Within the amount range, the adhesiveness of a coating to a substrate may be further improved.

Besides the above components, the photosensitive resin composition of the present invention may further include other additives such as an antioxidant, a stabilizer, and a radical capture as long as the physical properties of the composition are not adversely affected.

The photosensitive resin composition of the present invention may be used as a negative-type photosensitive resin composition. Particularly, the photosensitive resin composition may be coated on a substrate and cured to produce an insulating film.

The insulating film may be manufactured by a conventional method well known in the art. For instance, the photosensitive resin composition may be coated on a silicon substrate by a spin coating method; subjected to pre-bake at a temperature of, e.g., 60 to 130° C. for 60 to 130 seconds to remove the solvents; exposed to light using a photomask having a desired pattern; and subjected to development using a developing agent, for example, a tetramethylammonium hydroxide (TMAH) solution, to form a pattern on the coated film. The light exposure may be carried out at a wavelength ranging from 200 to 450 nm at the exposure intensity of 10 to 100 mJ/cm². Then, the coated film thus patterned is subjected to post-bake at a temperature of 150 to 300° C. for 10 minutes to 5 hours to manufacture a desired insulating film.

The photosensitive resin composition of the present invention may produce a pattern having high planarity and high resolution during the formation of a coated film. Thus, it is suitable as the material of an organic insulating film used in an LCD, and preferably used for preparing an organic insulating film functioning as white pixels at the same time. Additionally, it is useful for the material of electronic parts or devices in various fields.

### MODE FOR THE INVENTION

Hereinafter, the present invention is explained in detail with reference to the following examples. The examples are intended to further illustrate the present invention without limiting its scope.

In the following examples, the weight average molecular weight is determined by gel permeation chromatography (GPC) using a polystyrene standard.

### Preparation Example 1: Preparation of Copolymer (1-1)

A three-necked flask equipped with a condenser including a drying tube was placed on a stirrer with an automatic temperature controller. Then, 2 parts by weight of octyl mercaptan, 3 parts by weight of 2,2′-azobis(2,4-dimethyl valeronitrile), and 100 parts by weight of propylene glycol monomethyl ether acetate, based on 100 parts by weight of a monomer mixture were added to the flask, and nitrogen was changed thereto. In this case, the monomer mixture was composed of 20.5 mole % of methacrylic acid (MAA), 9 mole % of glycidyl methacrylate (GMA), 43 mole % of styrene (Sty), and 27.5 mole % of methyl methacrylate (MMA). Then, the temperature of the reaction mixture was elevated to 60° C. with slow agitation, and maintained for 5 hours for polymerization to obtain a copolymer solution (copolymer) having a weight average molecular weight of 5,400.

### Preparation Example 2: Preparation of Copolymer (1-2)

A copolymer solution having a weight average molecular weight of 3,800 was obtained by the polymerization reaction according to the same method as described in Preparation Example 1, with the exception that the monomer mixture composed of 21 mole % of methacrylic acid (MAA), 15 mole % of glycidyl methacrylate (GMA), 43 mole % of styrene (Sty), and 21 mole % of methyl methacrylate (MMA) was used.

### Preparation Example 3: Preparation of Copolymer (1-3)

A copolymer solution having a weight average molecular weight of 9,000 was obtained by the polymerization reaction according to the same method as described in Preparation Example 1, with the exception that the monomer mixture composed of 24 mole % of methacrylic acid (MAA), 56 mole % of styrene (Sty), and 20 mole % of methyl methacrylate (MMA) was used.

TABLE 1

| | Monomer mixture | | | | |
|---|---|---|---|---|---|
| | components (mole %) | | | | Weight average |
| | MAA | GMA | Sty | MMA | molecular weight |
| Copolymer | 20.5 | 9 | 43 | 27.5 | 5,400 |
| (1-1) | | | | | |
| Copolymer | 21 | 15 | 43 | 21 | 3,800 |
| (1-2) | | | | | |
| Copolymer | 24 | 0 | 56 | 20 | 9,000 |
| (1-3) | | | | | |

Photosensitive resin compositions of the following examples and comparative examples were prepared using the compounds prepared in the preparation examples.

The following compounds were used as other components.

Photopolymerization initiator (2-1): NCI-930 manufactured by ADEKA Co., Ltd.

Photopolymerization initiator (2-2): OXE-02 manufactured by BASF Co., Ltd.

Polymerizable unsaturated compound (3-1): dipentaerythritol hexa(meth)acrylate (DPHA)

Solvent (4-1): propylene glycol monomethyl ether acetate manufactured by Chemtronics Co., Ltd. (boiling point: about 146° C.)

Solvent (4-2): gammabutyrolactone manufactured by BASF Co., Ltd. (boiling point: about 204° C.)

Solvent (4-3): diethylene glycol monomethyl ether manufactured by TCI Co., Ltd. (boiling point: about 194° C.)

Solvent (4-4): diethylene glycol monobutyl ether manufactured by Daejung Chemicals & Metals Co., Ltd. (boiling point: about 230° C.)

Solvent (4-5): propylene glycol diacetate manufactured by Daejung Chemicals & Metals Co., Ltd. (boiling point: about 186° C.)

Solvent (4-6): diethylene glycol monoethyl ether manufactured by Daejung Chemicals & Metals Co., Ltd. (boiling point: about 202° C.)

Solvent (4-7): diethylene glycol monoethyl ether acetate manufactured by Daejung Chemicals & Metals Co., Ltd. (boiling point: about 214° C.)

Solvent (4-8): diethylene glycol monobutyl ether acetate manufactured by Daejung Chemicals & Metals Co., Ltd. (boiling point: about 241° C.)

Solvent (4-9): dipropylene glycol dimethyl ether manufactured by Hannong Chemicals (boiling point: about 178° C.)

Surfactant (5-1): FZ-2122 manufactured by Dow Corning Toray Silicon Co., Ltd.

Adhesion assisting agent (6-1): γ-isocyanatopropyltriethoxysilane manufactured by Shin-Etsu Co., Ltd.

### Example 1: Preparation of Photosensitive Resin Composition

Based on the solid content of 100 parts by weight of the copolymer (1-1) obtained in Preparation Example 1, 5.7 parts by weight of the photopolymerization initiator (2-1), 3.5 parts by weight of the photopolymerization initiator (2-2), 54 parts by weight of the polymerizable unsaturated compound (3-1), 0.2 parts by weight of the surfactant (5-1), and 0.8 parts by weight of the adhesion assisting agent (6-1), were mixed, and the solvent (4-1) and the solvent (4-2) were added thereto in a weight ratio of 80:20 in an amount such that the total solid content of the mixture was 23 wt %. The mixture was admixed with a shaker for 2 hours to prepare a liquid-phase photosensitive resin composition.

### Examples 2 to 8 and Comparative Examples 1 to 3: Preparation of Photosensitive Resin Compositions

Photosensitive resin compositions were prepared in accordance with the same procedure as described in Example 1, with the exception that the kind of the copolymer was changed as indicated in Table 2 below, and the kind and amount of the solvents were changed as shown in Table 3 below.

TABLE 2

| | Components of composition (parts by weight, solid content basis) | | | | | | | | | | | |
|---|---|---|---|---|---|---|---|---|---|---|---|---|
| | | | | | | | Polymerizable | | | | Adhesion | |
| | | | Photopolymerization | | | | unsaturated | | | | assisting | |
| | Copolymer | | initiator | | | | compound | | Surfactant | | agent | |
| Ex. 1 | 1-1 | 100 | 2-1 | 5.7 | 2-2 | 3.5 | 3-1 | 54 | 5-1 | 0.2 | 6-1 | 0.8 |
| Ex. 2 | 1-1 | 100 | 2-1 | 5.7 | 2-2 | 3.5 | 3-1 | 54 | 5-1 | 0.2 | 6-1 | 0.8 |
| Ex. 3 | 1-1 | 100 | 2-1 | 5.7 | 2-2 | 3.5 | 3-1 | 54 | 5-1 | 0.2 | 6-1 | 0.8 |
| Ex. 4 | 1-1 | 100 | 2-1 | 5.7 | 2-2 | 3.5 | 3-1 | 54 | 5-1 | 0.2 | 6-1 | 0.8 |
| Ex. 5 | 1-1 | 100 | 2-1 | 5.7 | 2-2 | 3.5 | 3-1 | 54 | 5-1 | 0.2 | 6-1 | 0.8 |
| Ex. 6 | 1-1 | 100 | 2-1 | 5.7 | 2-2 | 3.5 | 3-1 | 54 | 5-1 | 0.2 | 6-1 | 0.8 |
| Ex. 7 | 1-1 | 100 | 2-1 | 5.7 | 2-2 | 3.5 | 3-1 | 54 | 5-1 | 0.2 | 6-1 | 0.8 |
| Ex. 8 | 1-2 | 100 | 2-1 | 5.7 | 2-2 | 3.5 | 3-1 | 54 | 5-1 | 0.2 | 6-1 | 0.8 |
| Com. | 1-1 | 100 | 2-1 | 5.7 | 2-2 | 3.5 | 3-1 | 54 | 5-1 | 0.2 | 6-1 | 0.8 |
| Ex. 1 | | | | | | | | | | | | |
| Com. | 1-1 | 100 | 2-1 | 5.7 | 2-2 | 3.5 | 3-1 | 54 | 5-1 | 0.2 | 6-1 | 0.8 |
| Ex. 2 | | | | | | | | | | | | |
| Com. | 1-3 | 100 | 2-1 | 5.7 | 2-2 | 3.5 | 3-1 | 54 | 5-1 | 0.2 | 6-1 | 0.8 |
| Ex. 3 | | | | | | | | | | | | |

TABLE 3

Components of
solvents (wt %,
based on total solvent)

| | | | | |
|---|---|---|---|---|
| Ex. 1 | 4-1 | 80 | 4-2 | 20 |
| Ex. 2 | 4-1 | 80 | 4-3 | 20 |
| Ex. 3 | 4-1 | 80 | 4-4 | 20 |
| Ex. 4 | 4-1 | 80 | 4-5 | 20 |
| Ex. 5 | 4-1 | 80 | 4-6 | 20 |
| Ex. 6 | 4-1 | 80 | 4-7 | 20 |
| Ex. 7 | 4-1 | 80 | 4-8 | 20 |
| Ex. 8 | 4-1 | 80 | 4-2 | 20 |
| Com. Ex. 1 | 4-1 | 100 | — | — |
| Com. Ex. 2 | 4-1 | 80 | 4-9 | 20 |
| Com. Ex. 3 | 4-1 | 80 | 4-2 | 20 |

### Reference Example

Based on the solid content, 100 parts by weight of a copolymer (benzyl methacrylate/methacrylic acid/methyl methacrylate, 40/30/30 mole %, Mw 20,000), 65 parts by weight of the polymerizable unsaturated compound (3-1), 4 parts by weight of the photopolymerization initiator (2-1), 1.2 parts by weight of the photopolymerization initiator (2-2), 0.3 parts by weight of the surfactant (5-1), and 0.5 parts by weight of the adhesion assisting agent (6-1), were mixed, and 30 parts by weight of a blue pigment dispersant (containing 30% of the solid content) and the solvent (4-1) were added thereto, in an amount such that the total solid content of the mixture was 25%. The mixture was admixed with a shaker for 2 hours to prepare a photosensitive resin composition.

With respect to the photosensitive resin compositions prepared in the examples and comparative examples, the following items were evaluated.

### Experimental Example 1: Evaluation of Planarity

Step (1) Manufacture of Lower Cured Film

The photosensitive resin composition obtained in the Reference Example was coated on a glass substrate and was pre-baked on a hot plate having a temperature of 100° C. for 100 seconds to form a pre-baked film in a thickness of 4.3 μm. On the pre-baked film, a mask having a square pattern wherein the squares having a length of 150 μm and a width of 450 μm were disposed at intervals of 500 μm in a length, was applied so that the distance from the substrate was 200m. Then, the film was exposed to light emitted from an aligner (model: MA6) in a wavelength range from 200 nm to 450 nm at the exposure intensity of 100 mJ/cm² based on a wavelength of 365 nm. The film was developed by an aqueous solution of 0.04 wt % KOH as a developing agent, at 23° C. via spray nozzles for 120 seconds. Subsequently, the film thus developed was heated in a convection oven at 230° C. for 30 minutes to produce a lower cured film in a thickness of 3 μm.

Step (2) Manufacture of Organic Insulating Film

Each of the photosensitive resin compositions obtained in the examples and comparative examples was coated on the lower cured film by spin coating. The coated substrate was pre-baked on a hot plate having a temperature of 105° C. for 90 seconds to form a pre-baked film in a thickness of about 5 μm. The pre-baked film was exposed to light at the exposure intensity of 22 mJ/cm² based on a wavelength of 365 nm with the same aligner used for forming the previous pre-baked film for a certain time period. Subsequently, the film thus obtained was heated in a convection oven at 230° C. for 30 minutes to produce a cured film (organic insulating film).

Step (3) Measure of Planarity (Height Difference)

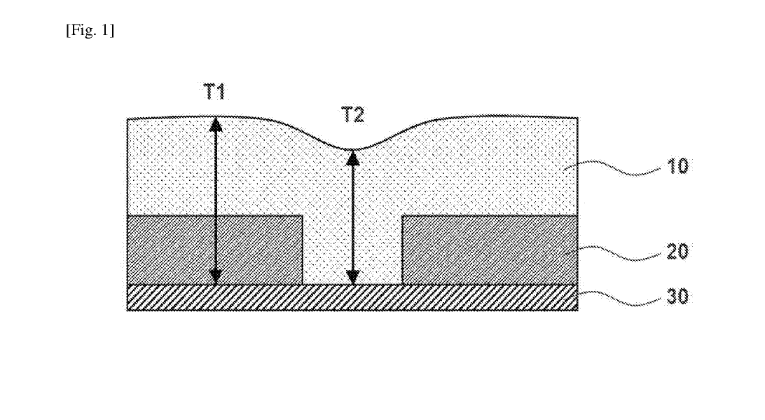

Referring to FIG. 1, a lower cured film (20) was formed on a substrate (30) by Step (1), and an organic insulating film (10) was formed on the lower cured film (20) by Step (2). In addition, due to the line-spaced pattern formed in the lower cured film (20), a region where the lower cured film (20) was formed and a region where the lower cured film (20) was not formed, were simultaneously present on the surface of the substrate (30). In this case, the height (T2) measured from the surface of the substrate (30) where the lower cured film (20) was not formed to the surface of the organic insulating film (10) may be smaller than the height (T1) measured from the surface of the substrate (30) where the lower cured film (20) was formed to the surface of the organic insulating film (10). Accordingly, the surface of the organic insulating film may not be planar.

The heights (T1 and T2) were measured using a three-dimensional surface measuring apparatus (SIS-2000 manufactured by SNU precision), and the planarity of the organic insulating film was calculated according to the following Mathematical Formula 1. The smaller the height difference value is, the better the planarity is.

Height Difference(Å)=T1−T2 [Mathematical Formula 1]

### Experimental Example 2: Evaluation of Resolution

Each of the compositions prepared in the examples and comparative examples was coated on a glass substrate by spin coating and the coated substrate was pre-baked on a hot plate having a temperature of 105° C. for 90 seconds to form a pre-baked film in a thickness of 4 μm. After disposing a mask having a square pattern with a 20 μm size so that the distance from the substrate was 10 μm, the pre-baked film was exposed to light for a certain time period at the exposure intensity of 22 mJ/cm² based on a wavelength of 365 nm with an aligner (model name: MA6) emitting light having a wavelength of 200 nm to 450 nm. Then, the film was developed using 2.38 wt % of a tetramethylammonium hydroxide aqueous developing agent through stream nozzles at 23° C. for 120 seconds. The film thus developed was then heated in a convection oven at 230° C. for 30 minutes to obtain a cured film.

The critical dimension (CD, line width, μm) of the hole pattern formed in the cured film using the mask having a square pattern with a 15 μm size was measured using a three-dimensional surface measuring apparatus (SIS-2000 manufactured by SNU precision), and the resolution (%) was calculated according to the following Mathematical Formula 2. The lower the resolution value (%) is, the better the resolution is.

Resolution (%)=[(15 μm−CD of hole pattern (μm))/15 μm]×100 [Mathematical Formula 2]

The resulting values obtained in the above experimental examples were evaluated according to the items indicated in Table 4 below, and are summarized in Table 5 below.

TABLE 4

| Score | Planarity (Height Difference, Å) | Resolution (%) |
|---|---|---|
| ∘ | 12,000 or less | 25% or less |
| x | Greater than 12,000 | Greater than 25% |

TABLE 5

| | Planarity | Resolution (%) |
|---|---|---|
| Ex. 1 | ∘ | ∘ |
| Ex. 2 | ∘ | ∘ |
| Ex. 3 | ∘ | ∘ |
| Ex. 4 | ∘ | ∘ |
| Ex. 5 | ∘ | ∘ |
| Ex. 6 | ∘ | ∘ |
| Ex. 7 | ∘ | ∘ |
| Ex. 8 | ∘ | ∘ |
| Com. Ex. 1 | x | ∘ |
| Com. Ex. 2 | x | x |
| Com. Ex. 3 | x | ∘ |

As shown in Table 5, the compositions according to the examples exhibited good planarity and resolution. In contrast, the compositions according to the comparative examples exhibited at least one unsatisfactory result in terms of the properties.

1. A photosensitive resin composition, comprising:
(1) a copolymer having a weight average molecular weight of 3,000 to 7,000;
(2) a polymerizable unsaturated compound;
(3) a photopolymerization initiator; and
(4) a solvent comprising a high boiling point solvent having a boiling point of 180° C. or higher in an atmospheric pressure.

2. The photosensitive resin composition of claim 1, wherein the high boiling point solvent is at least one selected from the group consisting of gamma butyrolactone, diethylene glycol monomethyl ether, diethylene glycol monobutyl ether, propylene glycol diacetate, diethylene glycol monoethyl ether, diethylene glycol monoethyl ether acetate, and diethylene glycol monobutyl ether acetate.

3. The photosensitive resin composition of claim 1, wherein the high boiling point solvent is comprised in an amount of 5 to 60 wt % on the basis of a total amount of the solvent.

4. The photosensitive resin composition of claim 1, wherein the high boiling point solvent is comprised in an amount of 15 to 40 wt % on the basis of a total amount of the solvent.

5. The photosensitive resin composition of claim 1, wherein the copolymer (1) comprises (1-1) a structural unit derived from an ethylenically unsaturated carboxylic acid, an ethylenically unsaturated carboxylic anhydride, or a mixture thereof, and (1-2) a structural unit derived from an ethylenically unsaturated compound containing an aromatic ring.

6. An organic insulating film manufactured by using the photosensitive resin composition described in any one of claims 1 to 5.
